(19) United States
(12) Patent Application Publication
(10) Pub. No.: US 2013/0005090 A1
(43) Pub. Date: Jan. 3, 2013

(54) METHOD FOR MANUFACTURING A SEMICONDUCTOR DEVICE HAVING A HEAT SPREADER

(76) Inventors: Yuko Sato, Kanagawa (JP); Takehiko Maeda, Kanagawa (JP); Fumiyoshi Kawashiro, Kanagawa (JP)

(21) Appl. No.: 13/610,460

(22) Filed: Sep. 11, 2012

Related U.S. Application Data
(63) Continuation of application No. 12/588,542, filed on Oct. 19, 2009.

(30) Foreign Application Priority Data
Oct. 23, 2008 (JP) 273141/2008

(51) Int. Cl. H01L 21/78

(52) U.S. Cl. 438/113; 257/E21.599

(57) ABSTRACT

A semiconductor device manufacturing method includes cutting a resin sealing body into a plurality of pieces, the resin sealing body including a plurality of semiconductor chips mounted on a wiring board, a heat spreader disposed above the plurality of the semiconductor chips, and a sealing resin filled between the wiring board and the heat spreader, wherein the cutting the resin sealing body includes shaving the resin sealing body from a side of the heat spreader, and shaving the resin sealing body from a side of the wiring board, wherein the shaving the resin sealing body from the side of the wiring board is carried out after the shaving from the side of the heat spreader, and wherein the resin sealing body is completely cut off by the shaving from the side of the wiring board, and mounting a group of ball-like electrodes at a back side of the wiring board.

The present application is a Continuation Application of U.S. patent application Ser. No. 12/588,542, filed on Oct. 19, 2009, which is based on and claims priority from Japanese patent application No. 2008-273141, filed on Oct. 23, 2008, the entire contents of which are incorporated herein by reference.

### BACKGROUND OF THE INVENTION

1. Field of the Invention

The present invention relates to a method for manufacturing a semiconductor device having a heat spreader.

2. Description of Related Art

The ball grid array (BGA) is one of the types of semiconductor devices. In case of this BGA type semiconductor device, semiconductor chips are mounted on a wiring board and sealed there with resin. In recent years, those semiconductor devices have been enhanced to meet the requirements of high density packaging and fast operation, thereby they have come to generate heat more and more. This is why there have been developed semiconductor packages having heat spreaders respectively to release the heat therefrom.

For example, JP-A-2003-249512 discloses a semiconductor package, in which a heat spreader is provided above the mounted semiconductor chips. JP-A-2006-294832 also discloses a method for manufacturing a semiconductor package having such a heat spreader. The MAP (Mold Array Package) technique is usually employed for manufacturing those semiconductor packages.

According to this MAP technique, plural semiconductor chips are mounted on one wiring board and sealed collectively there with resin to form a resin sealing body. This resin sealing body is cut into semiconductor device regions with use of a blade, thereby plural semiconductor packages are manufactured. If the MAP technique is employed for manufacturing semiconductor packages having heat spreaders respectively, the resin sealing body comes to be cut together with the heat spreader. In conjunction with this technique, JP-A-2003-249512, JP-A-Hei11 (1999)-214596, JP-A-2000-183218, JP-A-2003-37236, and JP-A-Hei4 (1992)-307961 disclose methods for cutting semiconductor packages with use of blades, respectively.

And the present inventor, as a result of the analysis of those conventional semiconductor devices, has found that the cutting methods, especially the cutting method disclosed in JP-A-2003-249512, have confronted with the following problems.

If a multilayer consisting of a wiring board, a sealing resin layer, and a heat spreader is cut at a time from the side of the wiring board with use of a blade, burrs might be generated at the cut face (end portion) of the heat spreader sometimes. This is because the heat spreader (e.g., copper) is soft and malleable in characteristics. And because the but has conductivity, the semiconductor device, if it is mounted on a board while a bur or a fragment of a pealed but is stuck to the semiconductor device, might cause a short circuit between the electrodes and/or between the wirings of the board.

### SUMMARY

According to one aspect of the present invention, the semiconductor device manufacturing method includes cutting a resin sealing body (10) into plural pieces (S50). The resin sealing body (10) consists of a plurality of semiconductor chips (2) mounted on a wiring board (1); a heat spreader (5) disposed above those semiconductor chips; and sealing resin (4) filled between the wiring board and the heat spreader. The cutting a resin sealing body (S50) includes shaving the resin sealing body (10) from a side of the heat spreader (S51) and shaving the resin sealing body (10) from a side of the heat spreader (S52).

If the resin sealing body (10) is cut off at a time from the side of the wiring board (1), a force is applied to the heat spreader (5) at the opposite side of the sealing resin (4), where the heat spreader (5) is not supported by anything. Consequently, burs come to be often generated at the end face of the heat spreader (5).

On the other hand, according to the present invention, the resin sealing body is shaved from the side of the heat spreader (5) during the shaving the resin sealing body from the side of the heat spreader (S51). In this process (S51), sealing resin (4) is provided in the direction in which the heat spreader (5) is pulled. And this sealing resin (4) presses and holds the heat spreader (5), thereby the heat spreader (5) is prevented from deformation. And, in the shaving the resin sealing body from the side of the wiring board (S52), there is no need to shave the heat spreader (5) or it is just required just to shave part of the heat spreader (5). In this case, therefore, an amount of shaving the heat spreader (5) can be reduced in the direction in which the heat spreader (5) is not supported by anything. Thus generation of burrs can be suppressed.

If the resin sealing body (10) is cut off at a time from the side of the heat spreader (5), the blade is pushed into the resin sealing body (10) at least up to the back side of the wiring board (1) (opposite side of the sealing resin (4)) after the blade tip comes in contact with the heat spreader (1). Meanwhile, the heat spreader (5) is pulled by a force of friction with the blade. As a result, sometimes the heat spreader (5) comes to be deformed partially in the direction of the wiring board due to the malleability of the heat spreader (5).

On the other hand, according to the present invention, in the shaving the resin sealing body (10) from the side of the wiring board (S52), at least part of the resin sealing body (10) is shaved from the side of the wiring board (1) in the direction of the thickness of the resin sealing body (10). Consequently, when shaving the resin sealing body (10) from the side of the heat spreader (5), it is just required to shave the resin sealing body (10) partially in the direction of the thickness. The heat spreader (5) is never pulled in the cutting process (S50), thereby the heat spreader (5) is suppressed from deformation.

Consequently the present invention can provide a method for manufacturing the semiconductor device capable of preventing the heat spreader more effectively from generation of burrs.

### BRIEF DESCRIPTION OF THE DRAWINGS

The above and other objects, advantages and features of the present invention will be more apparent from the following description of certain preferred modes taken in conjunction with the accompanying drawings, in which:

FIG. 1 is a schematic view of a semiconductor device of the BGA type;

FIG. 2 is a diagram for describing the manufacturing method for the semiconductor device;

FIG. 3 is another diagram for describing the manufacturing method for the semiconductor device;

FIG. 4 is another diagram for describing the manufacturing method for the semiconductor device;

FIG. 5 is another diagram for describing how to manufacture the semiconductor device;

FIG. 6 is a diagram for describing the burrs of a heat spreader;

FIG. 7A is a flowchart of the manufacturing processes of a semiconductor device in the first embodiment;

FIG. 7B is a flowchart of the manufacturing processes of the semiconductor device in the first embodiment, which includes a step of forming a resin sealing body in the BGA;

FIG. 7C is a flowchart of the manufacturing processes of the semiconductor device in the first embodiment in case of the LGA;

FIG. 7D is a flowchart of the manufacturing processes of the semiconductor device in the first embodiment with respect to the FCBGA;

FIG. 8A is a cross sectional view of the semiconductor device in the first embodiment with respect to the manufacturing method;

FIG. 8B is another cross sectional view of the semiconductor device in the first embodiment with respect to the manufacturing method;

FIG. 8C is another cross sectional view of the semiconductor device in the first embodiment with respect to the manufacturing method;

FIG. 8D is another cross sectional view of the semiconductor device in the first embodiment with respect to the manufacturing method;

FIG. 8E is another cross sectional view of the semiconductor device in the first embodiment with respect to the manufacturing method;

FIG. 8F is another cross sectional view of the semiconductor device in the first embodiment with respect to the manufacturing method;

FIG. 8G is another cross sectional view of the semiconductor device in the first embodiment with respect to the manufacturing method;

FIG. 9A is a diagram for describing how burrs are formed on the heat spreader;

FIG. 9B is another diagram for describing how burrs are formed on the heat spreader;

FIG. 9C is another diagram for describing how burrs are formed on the heat spreader;

FIG. 10A is a diagram for describing a difference of thickness between blades;

FIG. 10B is another diagram for describing a difference of thickness between blades;

FIG. 10C is another diagram for describing a difference of thickness between blades;

FIG. 11A is a diagram for describing a blade having a pointed end;

FIG. 11B is another diagram for describing a blade having a pointed end;

FIG. 11C is another diagram for describing a blade having a pointed end;

FIG. 12A is a diagram for describing a first depth t;

FIG. 12B is another diagram for describing the first depth t;

FIG. 13A is a schematic diagram for describing a structure of the semiconductor device;

FIG. 13B is another schematic diagram for describing the structure of the semiconductor device;

FIG. 13C is another schematic diagram for describing the structure of the semiconductor device;

FIG. 13D is another schematic diagram for describing the structure of the semiconductor device;

FIG. 14 is a flowchart of the manufacturing processes of a semiconductor device in the second embodiment;

FIG. 15A is a cross sectional view of the semiconductor device in the second embodiment with respect to the manufacturing method;

FIG. 15B is another cross sectional view of the semiconductor device in the second embodiment with respect to the manufacturing method;

FIG. 15C is another cross sectional view of the semiconductor device in the second embodiment with respect to the manufacturing method;

FIG. 15D is another cross sectional view of the semiconductor device in the second embodiment with respect to the manufacturing method;

FIG. 16A is a cross sectional view of the semiconductor device in the third embodiment with respect to the manufacturing method;

FIG. 16B is another cross sectional view of the semiconductor device in the third embodiment with respect to the manufacturing method;

FIG. 17A is a partial cross sectional view of the semiconductor device in the first embodiment, which is connected to a wiring board in the flip-chip mariner; and

FIG. 17B is a partial cross sectional view of a CoC type semiconductor device employed in the first embodiment.

### DETAILED DESCRIPTION OF THE PREFERRED EMBODIMENTS

### First Embodiment

Hereunder, there will be described the first embodiment of the present invention with reference to the accompanying drawings.

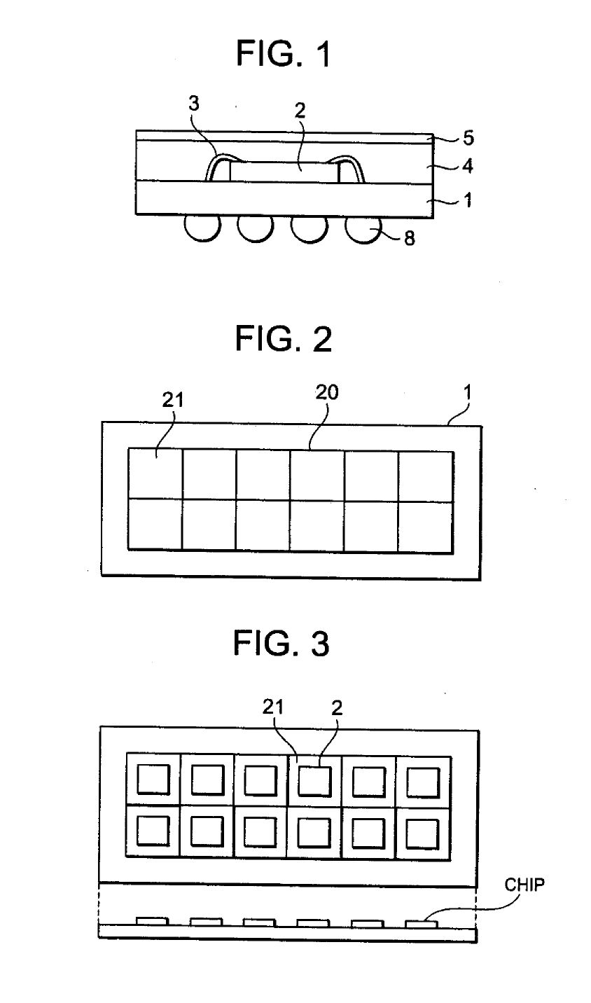

The semiconductor device in this first embodiment is configured as shown in FIG. 1. Concretely, the semiconductor device includes a wiring board 1; a semiconductor chip 2 mounted on the principal surface of the wiring board 1; sealing resin 4 that seals the semiconductor chip 2; and a heat spreader 5 disposed on the sealing resin 4. At the back side of the wiring board 1 is formed a group of ball-like electrodes 8.

The wiring board 1 may be, for example, a glass epoxy substrate formed as a multilayer consisting of an insulation layer and a copper wiring layer. The insulation layer is formed by impregnating resin in glass fiber. The wiring board 1 is, for example, 0.3 mm to 0.6 mm in thickness.

The sealing resin 4 protects the semiconductor chip 2 and functions to stick the heat spreader 5 to the semiconductor chip 2. The sealing resin 4 is, for example, 0.3 mm to 1.2 mm in thickness.

The heat spreader 5 is provided to release the heat generated from the semiconductor chip 2. The heat spreader 5 may preferably be made of metal, which is excellent in heat conductivity. More concretely, the heat spreader 5 may be made of copper, aluminum, iron, or the like. The heat spreader 5 is, for example, 0.1 mm to 0.5 mm in thickness. The surface of the heat spreader 5 may be covered. For example, the surface of the heat spreader may be covered by a film of Alumite or the like.

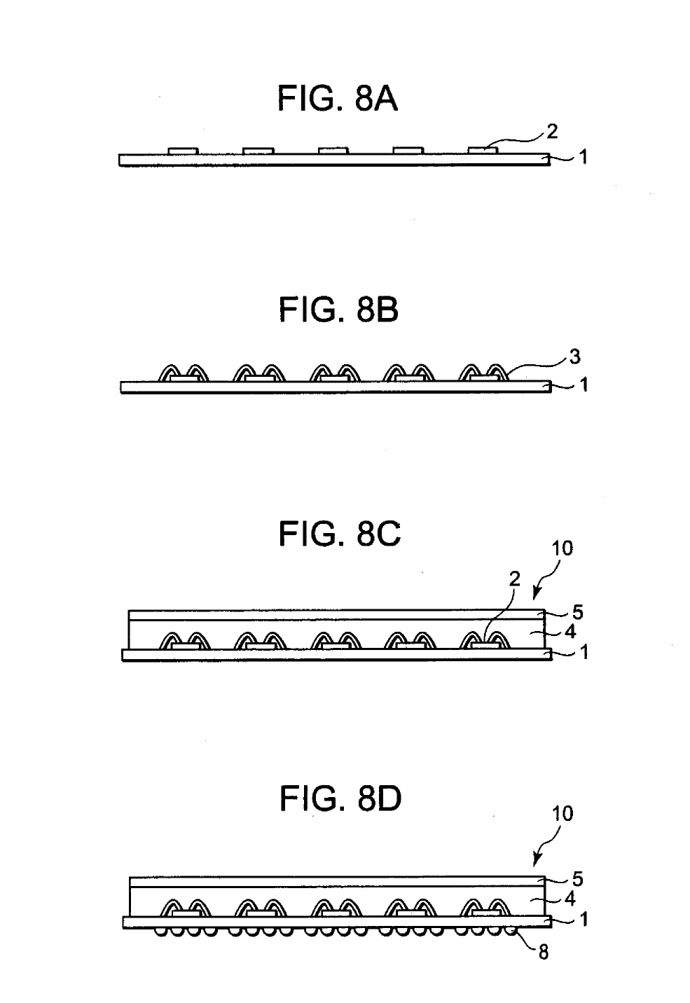

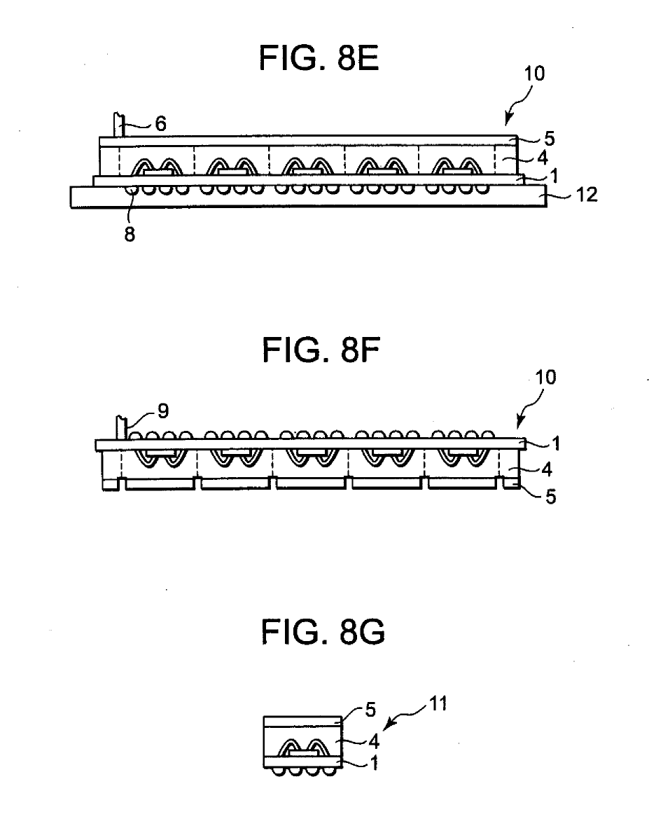

Next, there will be described how to manufacture the semiconductor device. FIGS. 7A, 7B, and 7C are flowcharts for describing the manufacturing processes of the semiconductor device. FIGS. 8A through 8G are cross sectional views of the semiconductor device with respect to the manufacturing processes.

If a resin sealing body in which both a semiconductor chip and a heat spreader are sealed is already prepared, control goes to the process shown in FIG. 7A. In the process shown in FIG. 7A, the resin sealing body 10 is just cut into pieces (S50).

On the other hand, a resin sealing body is to be manufactured first, control goes to the process shown in FIG. 7B. In the process shown in FIG. 7B, the semiconductor chip is connected to the wiring board in a wire bonding process. In FIG. 7B is shown a BGA (Ball Grid Array) in which ball electrodes 8 are formed on the wiring board, In addition to the BGA in which ball electrodes 8 are formed on the wiring board 1 in the process shown in FIG. 7B, the present invention can also employ the LGA (Land Grid Array). FIG. 7C shows the LGA case. In case of this LGA, ball electrodes 8 are replaced with pad electrodes, which are formed on the back side of the wiring board 1. Thus the ball mounting process (S40) can be omitted.

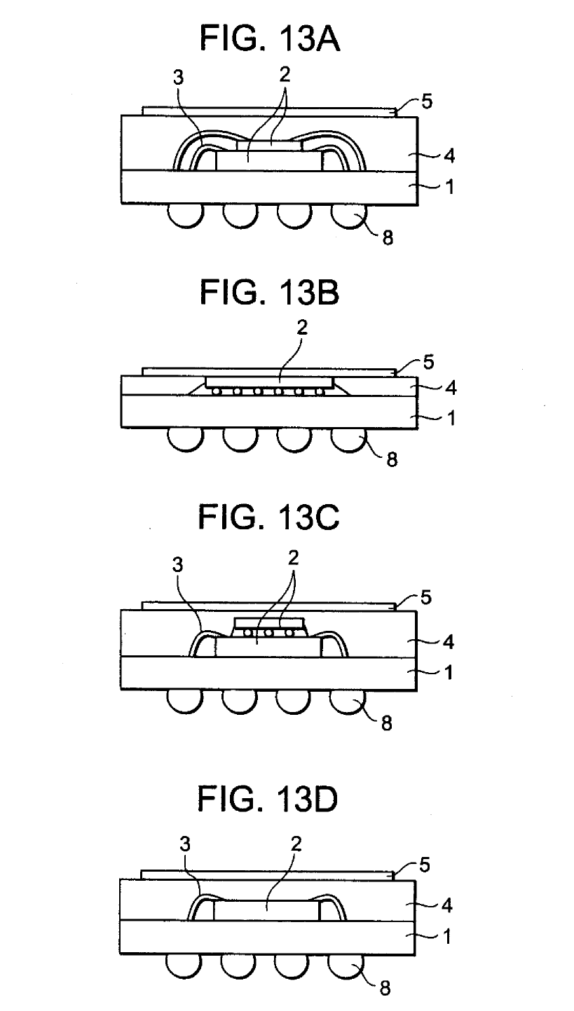

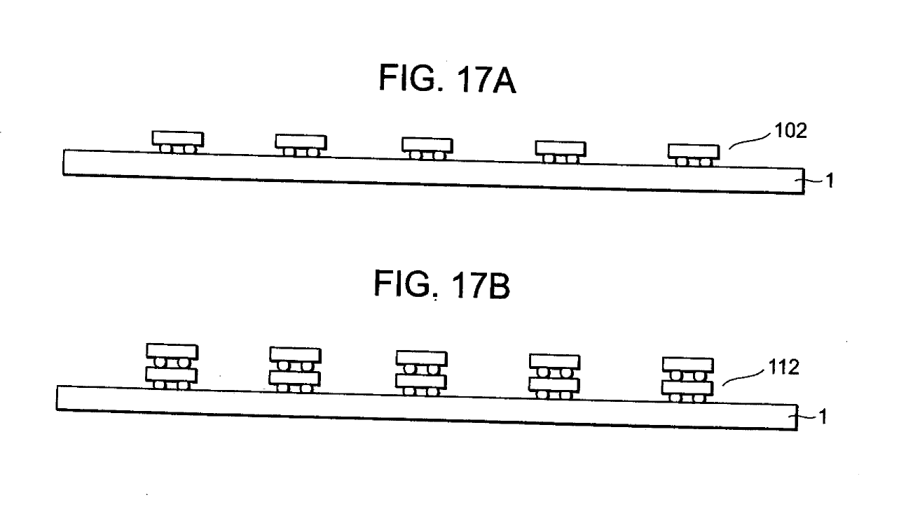

FIG. 7D shows a manufacturing process that employs the FCBGA (Flip Chip Ball Grid Array). In case of the FCBGA, as shown in FIG. 17A, the semiconductor chip 2 and the wiring board 1 are connected to each other through ball electrodes in a manner of the flip chip connection 102. Consequently, the wire bonding process can be omitted. The semiconductor chip is completed as shown in, for example, FIG. 13B (the ball electrodes between the wiring board and the semiconductor chip are simplified in the illustration of FIG. 17A). Furthermore, as shown in FIG. 17B, the semiconductor chip is formed in layers connected to each other (CoC: Chip on Chip 112) through ball electrodes in the manner of the flip chip connection and mounted on the wiring board 1.

Hereunder, there will be described how to manufacture the semiconductor device on the basis of the process shown in FIG. 7B.

Step S10; Mounting Semiconductor Chips

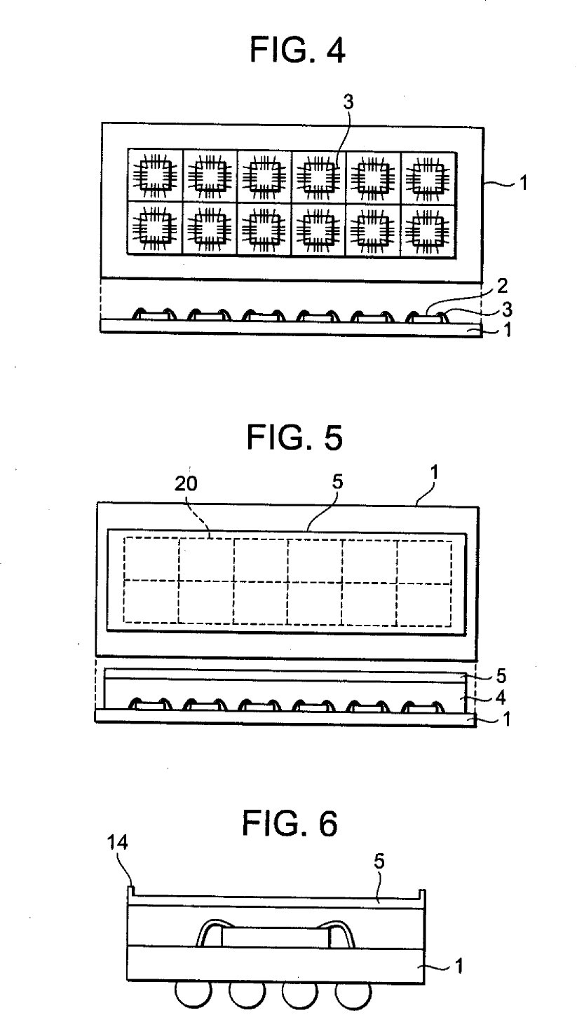

At first, as shown in FIG. 8A, the wiring board 1 is prepared. Then, plural semiconductor chips 2 are mounted on the principal surface of the wiring board 1. FIG. 2 is a top view of the wiring board for showing the layout of the product area 20 and the unit product areas 21. The product area 20 is divided into unit product areas 21. Finally, the unit product areas 21 are separated from each other as semiconductor packages as shown in FIG. 1. In FIG. 2, the product area 20 and each unit product area 21 are partitioned by lines. Actually, however, they are not necessarily partitioned by lines such way.

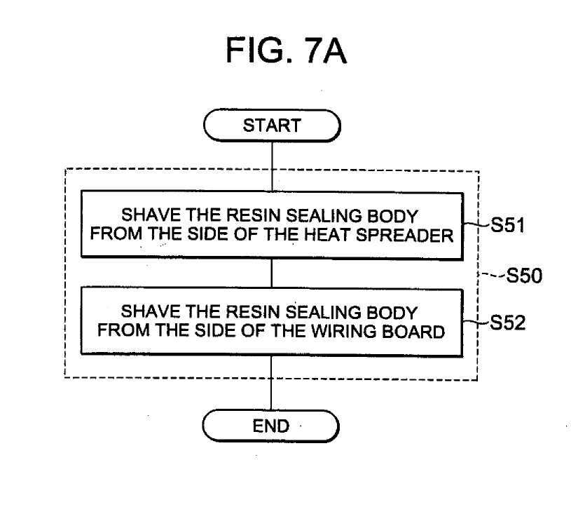

FIG. 3 is a top view of each semiconductor chip 2 disposed in each unit product area 21.

Step S15; Wire Bonding

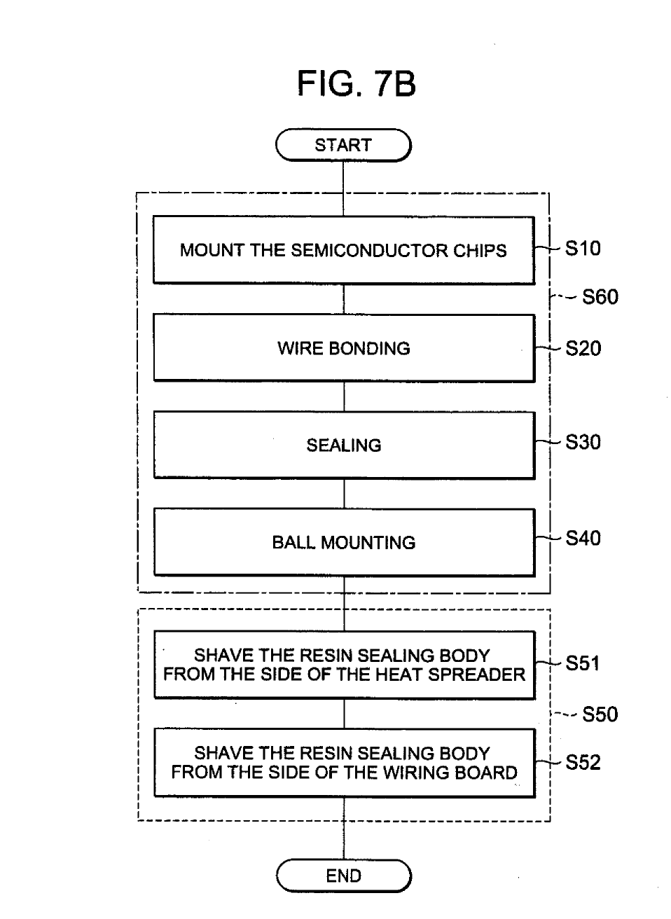

Next, as shown in FIG. 8B, a process of wire bonding is carried out to connect each of the semiconductor chips 2 electrically to the wiring board 1 by wire 3. FIG. 4 is a top view of the wire-bonded semiconductor chips 2.

Step S20; Disposing the Heat Spreader 5

Next, as shown in FIG. 8C, the heat spreader 5 is disposed above the semiconductor chips 2 so as to face the principal surface of the wiring board 1.

Step S30; Sealing

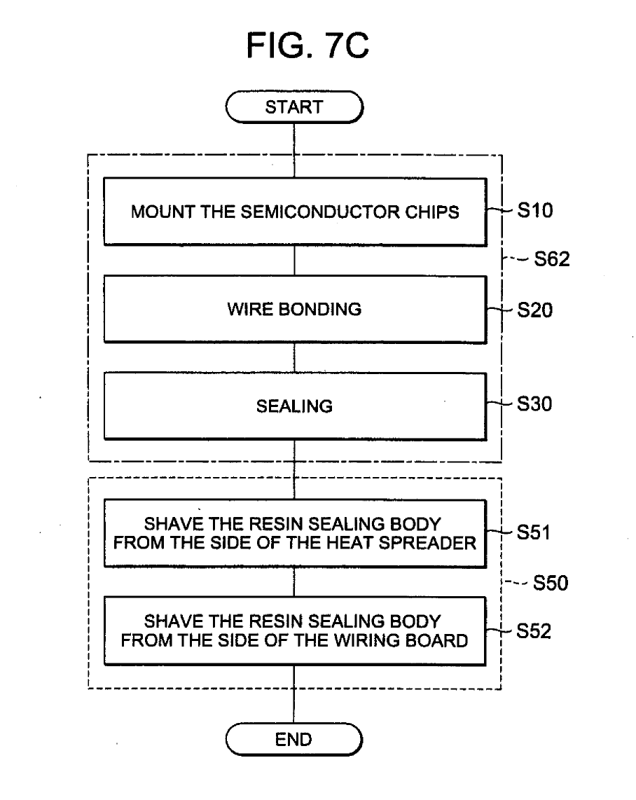

Then, sealing resin 4 is supplied between the wiring board 1 and the heat spreader 5 and hardened there. Consequently, the plural semiconductor chips 2 are sealed together by the sealing resin 4. FIG. 5 shows a top view of the sealed semiconductor chips 2. Thereby the resin sealing body 10 is completed.

Step S40; Ball Mounting

Next, as shown in FIG. 8D, the group of ball electrodes 8 is formed at the back side of the wiring board 1.

Step S50; Cutting

Next, a disc blade is turned and put in contact with the resin sealing body 10 so as to shave the resin sealing body 10.

Concretely, as shown in FIG. 8E, a blade 6 is used to shave the resin sealing body 10 from the heat spreader 5 side (S51). At this time, the resin sealing body 10 is disposed on a stage (not shown), for example, so that the heat spreader 5 comes upward in the shaving process. In this process, it is just required to shave at least part of the heat spreader 5. In this case, the ball electrodes 8 might make the resin sealing body 10 unstable in positioning. To prevent this, therefore, a sheet 12 of which elasticity is lower than that of the ball electrodes should preferably be disposed between the stage and the resin sealing body 10. The disposition of the elastic sheet 12 could prevent the ball electrodes 8 from being crushed by the force applied from the blade 6.

After the process for shaving the resin sealing body 10 from the heat spreader 5 side, the resin sealing body 10 is disposed so that the back side (on which the ball electrodes 8 are formed) comes upward as shown in FIG. 8F. Then, the resin sealing body 10 is shaved from the wiring board 1 side with use of the disc blade 9 (S52). In this step, the resin sealing body 10 is cut into plural semiconductor devices 11 as shown in FIG. 8G. At this time, just like in step S51, an elastic sheet should preferably be disposed between the stage and the heat spreader 5 so as to prevent the surface of the heat spreader 5 from damages.

This completes the description of how to manufacture the semiconductor device in this first embodiment by the processes in the steps S10 to S50 described above. And according to this first embodiment, in the step (S50) of cutting the resin sealing body 10 into pieces, two steps (S51) and (S52) are carried out to forward the cutting from the heat spreader 5 side and the cutting from the wiring board 1 side. Thus bur generation can be suppressed. This reason will be described below more in detail.

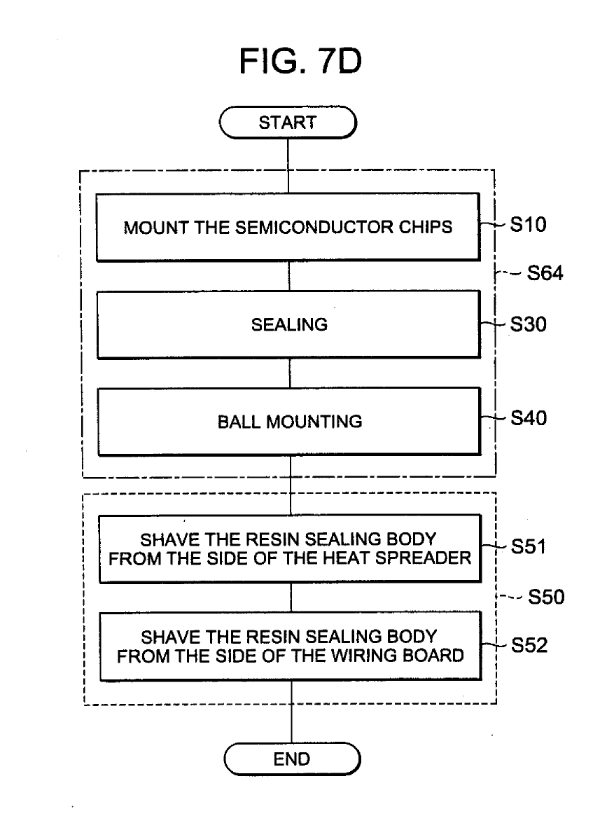

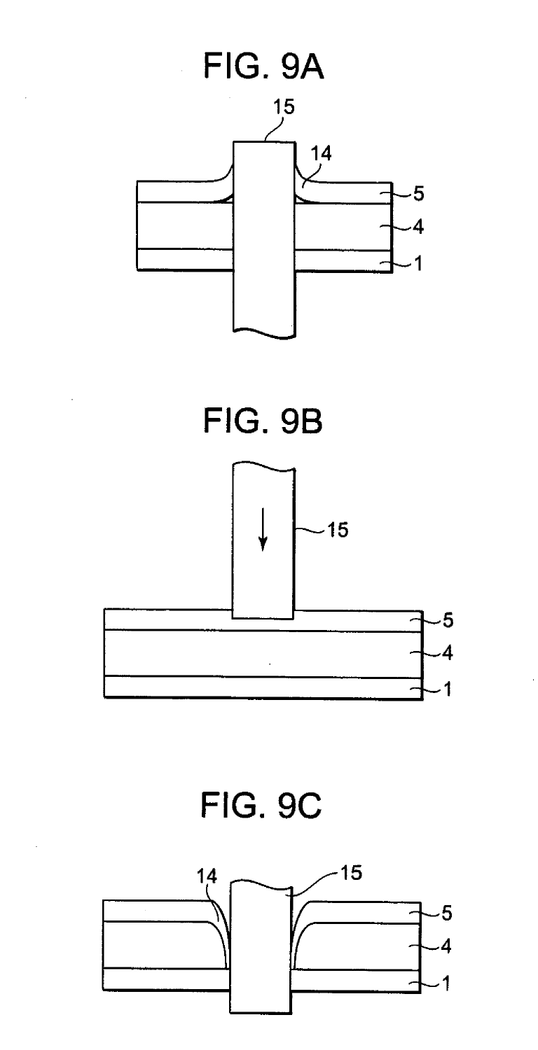

At first, there will be described a case in which the resin sealing body 10 is cut into pieces at once from the wiring board 1 side. FIG. 9A is a diagram for describing how the rein sealing part 10 is cut such way. In the resin sealing body 10, the heat spreader 5 rubs against the blade 15, thereby a stress is generated to move the heat spreader 5 toward the opposite side of the resin sealing. And because there is nothing to prevent the heat spreader 5 from deformation at the opposite side of the sealing resin, burrs 14 come to be easily formed at the heat spreader. After the heat spreader cutting, the burrs 14 are formed, for example, as shown in FIG. 6.

On the other hand, according to this first embodiment, in the step (S51) of shaving the resin sealing body 10 from the heat spreader 5 side, at least part of the heat spreader 5 is shaved. In this step (S51), the sealing resin 4 is provided in the direction in which the heat spreader 5 is pulled. And this sealing resin 4 can keep the heat spreader 5 stay as is, thereby the heat spreader 5 is suppressed from deformation. And because the resin sealing body 10 is shaved partially in the step (S51), the heat spreader 5 is not required to be shaved or it is just required to be shaved partially. Consequently, an amount of shaving can be reduced for the heat spreader 5 in the direction in which there is nothing to disturb the shaving (direction from the wiring board 1 to the heat spreader 5). Thus generation of burrs can be suppressed.

Next, there will be described a case in which the resin sealing body 10 is cut into pieces at once from the heat spreader 5 side. FIGS. 9B and 9C show how the resin sealing body 10 is cut into pieces such way. In this case, the tip of the blade 15 comes in contact with the heat spreader 5 (FIG. 9B), then it is pushed into the heat spreader 5 up to the opposite side surface (FIG. 9C). Meanwhile, a tensile stress generated from the friction with the blade 15 is applied to the heat spreader 5. And because the blade 15 is pushed deeply into the heat spreader 5, the force applied to the heat spreader 5 also increases. Consequently, even while the sealing resin is provided in the direction in which the heat spreader is pulled, the heat spreader might come to be deformed, thereby burrs are generated sometimes.

On the other hand, according to this first embodiment, in the step (S52) of shaving the resin sealing body 10 from the wiring board 1 side, the shaving advances for at least part of the resin sealing body 10 in the direction of the thickness, Consequently, in the step (S51) of shaving from the heat spreader 5 side, it is just required to shave part of the resin sealing body 10 in the direction of the thickness. Thus the tensile force to be applied to the heat spreader 5 can be reduced, thereby generation of burrs can be suppressed. Usually, if burrs are generated, those burrs must be removed to assure the product safety. And because the present invention can suppress generation of burrs as described above, no further process is required for removing burrs. And although the cutting is made with use of a blade in two steps according to the present invention as described above, the total number of processes is still less than in any conventional manufacturing methods.

Next, there will be described a disc blade used for the cutting step (S50).

In the step (S51) of shaving from the heat spreader 5 side, a blade 6 (hereinafter, to be referred to as the heat spreader blade 6) is used to shave the malleable heat spreader 5. In order to prevent the blade 6 from clogging to be caused by the malleability of the heat spreader 5, the blade 6 is provided with rough (large size) abrasive grains (e.g., diamond grains) at its tip. The abrasive grains are stuck to the tip with thermal setting resin.

On the other hand, another type blade 9 (hereinafter, to be referred to as the wiring board blade 9) is used for the step (S52) of shaving from the wiring board 1 side. The blade 9 is required to shave both the wiring board 1 and the sealing resin 4. The wiring board blade 9 and the heat spreader blade 6 should not be the same. Otherwise, because the blade 6 has rough abrasive grains, if the blade 6 is used for shaving the sealing resin 4, the cut cross section becomes rough. Usually, the abrasive grains (e.g., diamond grains) of the wiring board blade 9 is finer (small size) than those of the blade 6.

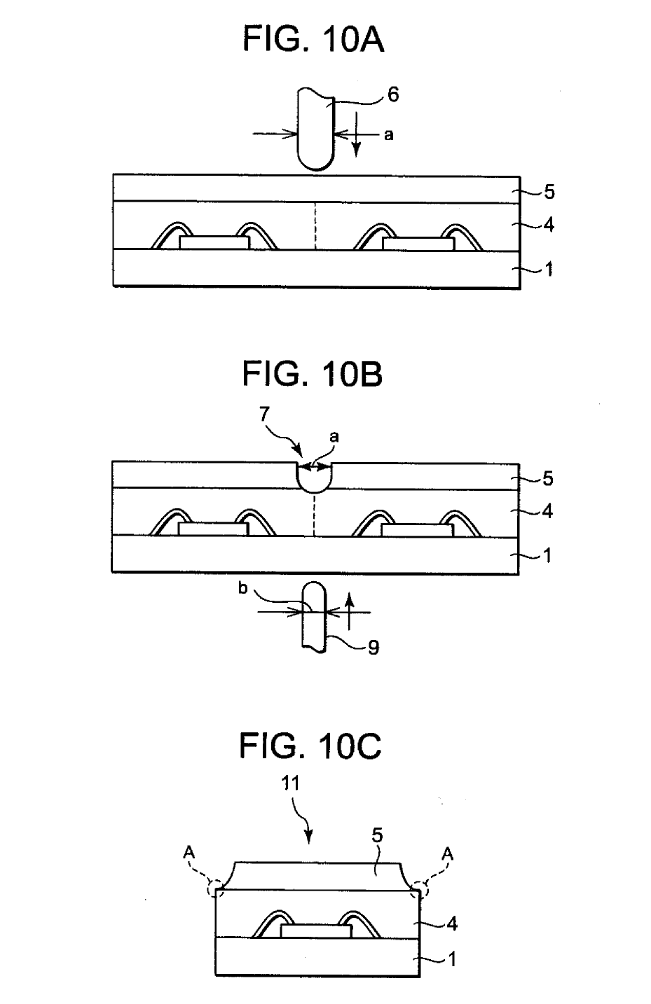

The blade thickness should also be different between the heat spreader blade 6 and the wiring board blade 9. Concretely, the blade used first should be thicker than the blade used later. This means that the heat spreader blade 6 should be thicker than the wiring board blade 9 in this first embodiment. As shown in FIG. 10A, the heat spreader blade 6 is assumed to be ‘a’ in thickness. In this case, in the step (S51) of shaving from the heat spreader 5 side, a groove is formed at a width of around ‘a’ (FIG. 10B). And as shown in FIG. 10B, the wiring board blade 9 is assumed to be ‘b’ in thickness. If ‘b’ is thinner than ‘a’ at this time, the resin sealing body 10 can be cut without generating any burrs even when the wiring board blade 9 is slightly off the position in the step (S52). FIG. 13D shows a structure of the completed semiconductor device in such a case. The cutting face of the heat spreader 5 is inside the cutting face of the wiring board 1. Consequently, the heat spreader 5 can be prevented from peeling more effectively than when the heat spreader 5 and the wiring board 1 are aligned at their cutting faces.

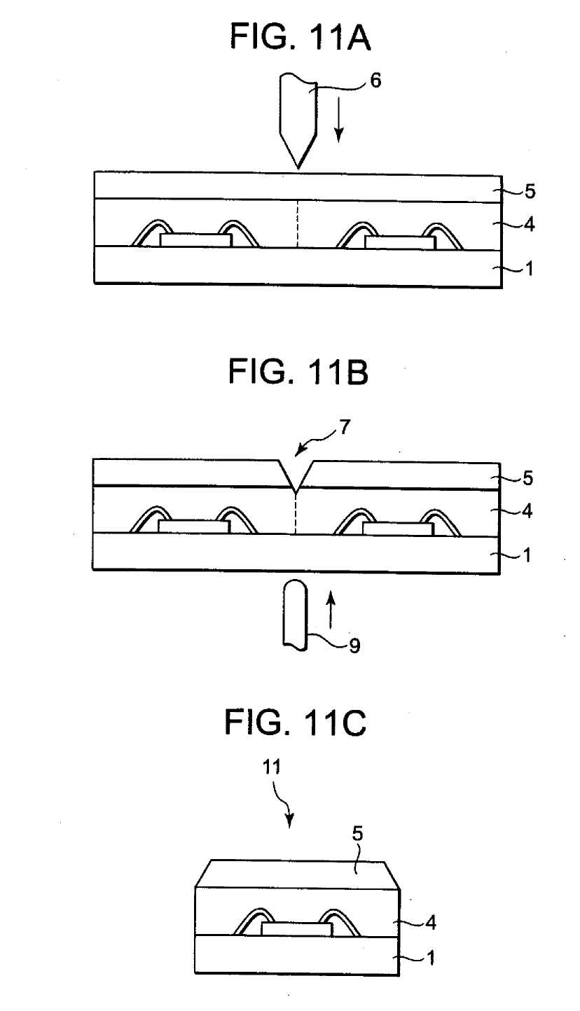

Furthermore, as shown in FIG. 10A, the tip of the heat spreader blade 6 may be rounded. In such a case, the cutting face of the heat spreader 5 becomes as shown in FIG. 10C. The tip of the blade may be pointed. However, the tip should preferably be pointed like the V-letter, for example, as shown in FIG. 11A. The use of the blade 6 of which tip is pointed such way can form the V-letter groove 7 as shown in FIG. 11B. Furthermore, because the angle between the cutting face and the top face of the heat spreader 5 is wide, the use of the blade 6 of which tip is pointed as described above enables the end portion of the heat spreader 5 to be shaped just like it is rounded automatically as shown in FIG. 11C.

Next, there will be described the depth (the first depth t) of the resin sealing body 10 to be shaved in the step (S51) of shaving from the heat spreader 5 side.

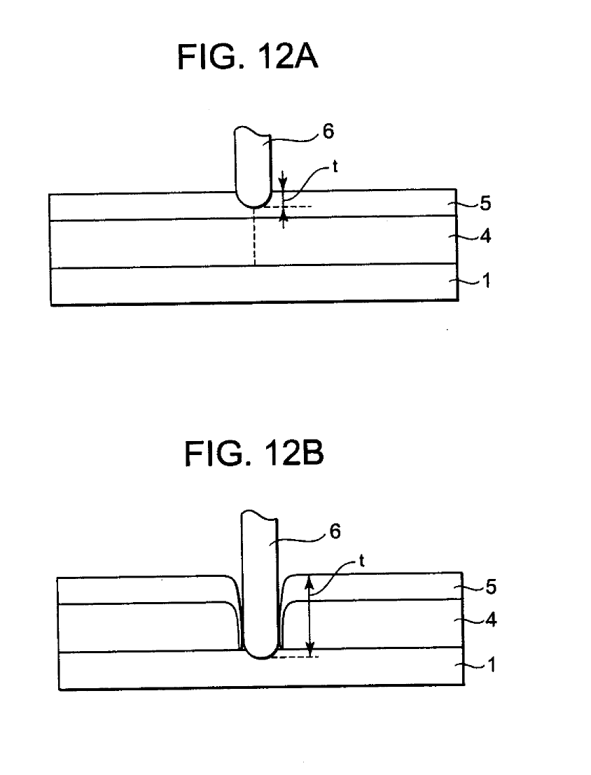

At first, a preferable first depth t will be described with reference to FIGS. 12A and 12B. The first depth t should preferably be made so as to enable the heat spreader 5 to be cut off completely. This means that the first depth t should preferably be over the thickness of the heat spreader 5. If the first depth t is under the thickness of the heat spreader 5, part of the heat spreader 5 will come to be left over as shown in FIG. 12A. In order to prevent this, therefore, in the step (S52) of shaving from the wiring board 1 side, it is required to shave the left-over part of the heat spreader 5. While generation of burrs can be suppressed more effectively in this case than the shaving the whole heat spreader 5 from the wiring board 1 side, the heat spreader 5 comes to be pulled in the direction in which there is nothing to hold itself. Thus generation of burrs might not be prevented completely. On the other hand, if the first depth t is enough to cut the heat spreader 5 off completely, shaving of the heat spreader 5 can be omitted in the step (S52) of shaving from the wiring board 1 side. Consequently, the heat spreader 5 is not pulled in the direction in which there is nothing to hold itself, thereby generation of burrs can be prevented more surely.

Furthermore, the first depth t should preferably not reach the wiring board 1. In the step (S51) of shaving from the heat spreader 5 side, if the resin sealing body 10 is shaved up to the wiring board 1, the heat spreader 5 pulled by the blade 6 might come in touch with the wiring board 1. In such a case, the wiring patterns formed on the wiring board 1 might be short-circuited with each other. If the first depth t does not reach the wiring board 1, such apprehension is removed.

More preferably, the first depth t should be under the depth of “thickness of the heat spreader 5+0.2 mm.” As described above, the fine abrasive grains are provided minutely at the tip of the heat spreader blade 6. If the blade 6 is used to shave a large quantity of the sealing resin 4, the blade 6 might be clogged. This clogging can be prevented, however, if the first depth t is under the depth of “thickness of the heat spreader 5+0.2 mm.” This is because the amount of the sealing resin 4 to be shaved by the heat spreader blade 6 can be reduced significantly. And the blade 6 can also be prevented from such clogging, as well.

In this first embodiment, the step (S51) of shaving from the heat spreader 5 side is carried out in prior to the step (S52) of shaving from the wiring board 1 side. However, the order of those steps (S51) and (S52) may be changed. For example, the step (S52) may be carried out in prior to the step (S51).

Furthermore, in this first embodiment, the semiconductor device is a BGA type one in which the semiconductor chip 2 is connected to the wiring board 1 by wire as shown in FIG. 1. However, the structure of the semiconductor device may be variable. For example, the stacked MCP (Multi Chip Package) structure as shown in FIG. 13A may be employed for the semiconductor device. In case of this stacked MCP structure, plural semiconductor chips are stacked on a wiring board 1. The flat MCP structure may also be employed for the structure of the semiconductor device. In case of this structure, plural semiconductor chips are flat-disposed on a wiring board. In case of the stacked/flat MCP, plural semiconductor chips 2 are provided in one semiconductor device. Each of those semiconductor chips 2 is connected to the wiring board 1 by wire. The semiconductor device in this first embodiment may also be an FCBGA (Flip-chip Ball Grid Array) one as shown in FIG. 13B. In this case, each semiconductor chip 2 is disposed so that the electrode-formed surface faces the wiring board 1. The semiconductor device in this first embodiment may also be a COC (Chip on Chip)/wire mixed packaged one as shown in FIG. 13C. Plural semiconductor chips 2 are provided in the COC/wire mixed packaged semiconductor device. The plural semiconductor chips include a first semiconductor chip connected through wire 3 to the wiring board 1 and a second semiconductor chip formed on the first semiconductor chip. The second semiconductor chip is disposed so that the electrode formed-surface faces the first semiconductor chip. In case of any of the FCBGA semiconductor device and the COC/wire mixed packaged semiconductor device, the heat spreader 5 may be in contact with the back side of each semiconductor chip 2 or it may not be contact with each semiconductor chip 2. However, the heat spreader 5 should preferably be in contact with each semiconductor chip 2 from the viewpoint of heat releasing.

### Second Embodiment

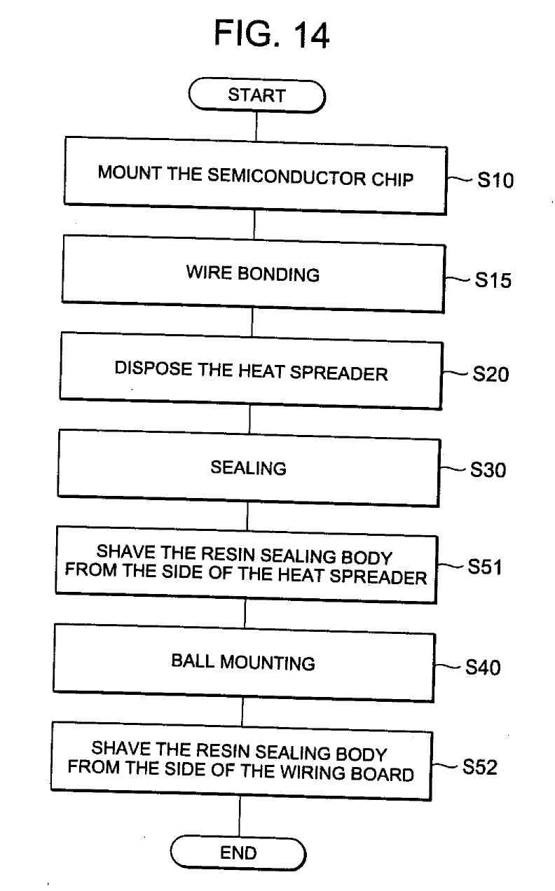

Next, there will be described the second embodiment of the present invention. FIG. 14 is a flowchart of the manufacturing processes for the semiconductor device in this second embodiment. In this second embodiment, the order of the ball mounting process (S40) is changed from that in the first embodiment. Others are the same as those in the first embodiment, so that detailed descriptions for them will be omitted here.

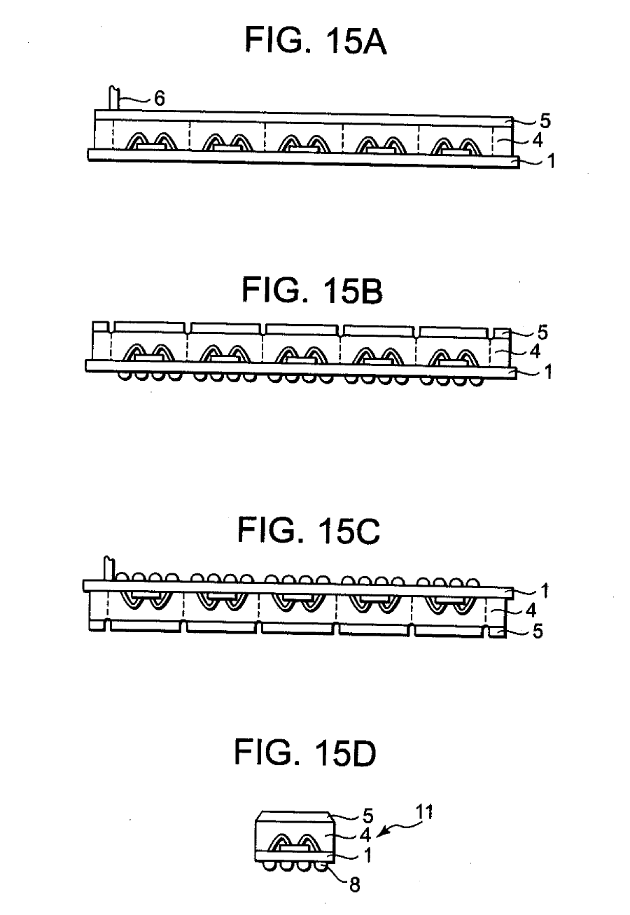

FIGS. 15A through 15D are cross sectional views of the semiconductor device in this second embodiment with the manufacturing processes.

Just like in the first embodiment, the processes from the step S10 to the step S30 are carried out. After ending the processing in step S30, the step (S51) of shaving from the heat spreader 5 side is carried out (FIG. 15A). After this, the ball mounting step (S40) is carried out (FIG. 15B). Then, the step (S52) of shaving from the wiring board 1 side is carried out (FIG. 15C). After ending the step (S52), the resin sealing body 10 is cut into plural semiconductor chips of the semiconductor device (FIG. 15D).

According to this second embodiment, the ball mounting step is carried out after the step (S51) of shaving from the heat spreader 5 side. Consequently, in the step (S51) of shaving from the heat spreader 5 side, the ball electrodes 8 are not formed yet. Consequently, the resin sealing body 10 can be stabilized without using the elastic sheet 12 that is required in the first embodiment.

### Third Embodiment

Next, there will be described the third embodiment of the present invention. In this third embodiment, the step (S51) of shaving from the heat spreader 5 side is improved from those in the above first and second embodiments. Others are the same as those in the first and second embodiments, so that detailed descriptions for them will be omitted here.

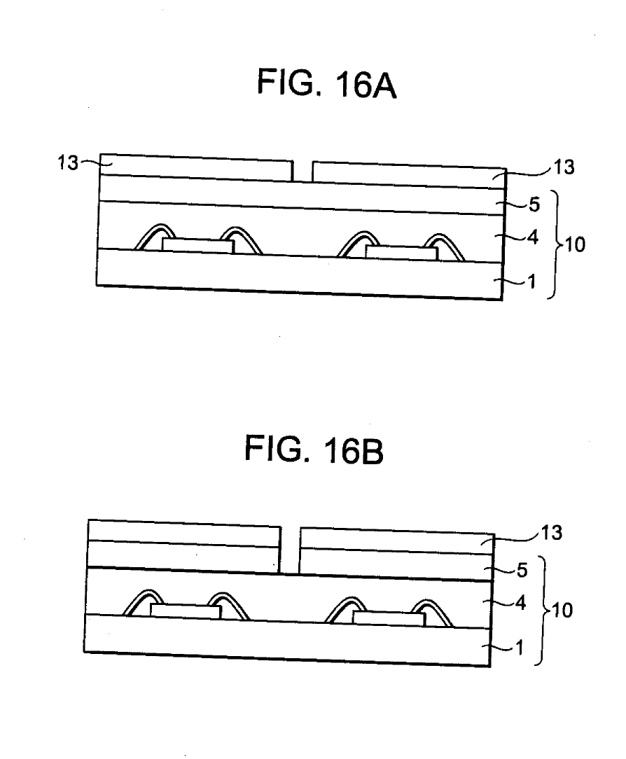

FIGS. 16A and 16B are cross sectional views of a semiconductor device in this third embodiment with respect to the step (S51) of shaving from the heat spreader 5 side.

At first, as shown in FIG. 16A, a coat of resist 13 is applied onto the heat spreader 5 of the resin sealing body 10. Then, an opening is formed in the resist 13 along each portion to be cut off.

After this, as shown in FIG. 16B, the heat spreader 5 is subjected to chemical etching to be carried out with an etching fluid and by using the resist 13 as a mask. As the etching fluid, for example, a compound aqueous liquid of NH₄OH and H₂O₃ is used. For another example, an aqueous solution of sodium hydroxide is used as the etching fluid.

After this, just like in the above first and second embodiments, the steps including the step (S52) of shaving from the wiring board 1 side are carried out to obtain plural semiconductor devices 11.

According to this third embodiment, therefore, the heat spreader 5 is shaved by the etching fluid, not shaved mechanically. Consequently, the heat spreader 5 is not pulled by the blade 6 and the heat spreader 5 can be prevented more effectively from generation of burrs.

What is claimed is:

1. A semiconductor device manufacturing method, said method comprising:
cutting a resin sealing body into a plurality of pieces, the resin sealing body comprising a plurality of semiconductor chips mounted on a wiring board, a heat spreader disposed above the plurality of the semiconductor chips, and a sealing resin filled between the wiring board and the heat spreader,
wherein the cutting the resin sealing body includes:
shaving the resin sealing body from a side of the heat spreader; and
shaving the resin sealing body from a side of the wiring board,
wherein the shaving the resin sealing body from the side of the wiring board is carried out after the shaving from the side of the heat spreader, and
wherein the resin sealing body is completely cut off by the shaving from the side of the wiring board; and
mounting a group of ball-like electrodes at a back side of the wiring board prior to the shaving from the side of the wiring board and the shaving from the side of the heat spreader,
wherein the shaving the resin sealing body from the side of the heat spreader forms a ditch extending from a surface of the heat spreader to a middle of the sealing resin, and the shaving the resin sealing body from the side of the wiring board forms a slit extending from a surface of the back side of the wiring board to a bottom of the ditch formed in the sealing resin.

2. The method according to claim 1, wherein the heat spreader comprises a metal.

3. The method according to claim 2, wherein the shaving the resin sealing body from the side of the heat spreader includes shaving the resin sealing body with a first blade.

4. The method according to claim 3, wherein the heat spreader is completely cut off in the shaving the resin sealing body from the side of the heat spreader.

5. The method according to claim 4, wherein a width of a ditch to be formed by the shaving the resin sealing body from the side of the heat spreader is wider than a width of a slit to be formed by the shaving the resin sealing body from the side of the wiring board.

6. The method according to claim 4, wherein the first blade has a pointed end.

7. The method according to claim 4, wherein the first blade has a rounded end.

8. The method according to claim 3, wherein the shaving the resin sealing body from the side of the wiring board includes shaving the resin sealing body with a second blade.

9. The method according to claim 8, wherein the first blade has rougher abrasive grains than abrasive grains of the second blade.

10. The method according to claim 2, wherein the shaving the resin sealing body from the side of the heat spreader includes etching the heat spreader.

11. The method according to claim 2, wherein a surface of the heat spreader is covered by a film.

12. The method according to claim 1, further comprising:
forming the resin sealing body in prior to the cutting the resin sealing body,
wherein the forming the resin sealing body includes:
mounting the plurality of the semiconductor chips on a principal surface of the wiring board;
disposing the heat spreader above the plurality of the semiconductor chips; and
sealing the plurality of the semiconductor chips with the sealing resin supplied between the heat spreader and the wiring board, thereby forming the resin sealing body.

13. The method according to claim 1, wherein the resin sealing body is shaved partially in the shaving from the side of the heat spreader.

14. The method according to claim 1, wherein the shaving the resin sealing body from the side of the heat spreader comprises using a first blade having abrasive grains which are rougher than abrasive grains of a second blade used in the shaving the resin sealing body from the side of the wiring board.

15. The method according to claim 1, wherein a depth of the ditch in a shaving direction of the resin sealing body is greater than a depth of the heat spreader.

16. The method according to claim 1, wherein the bottom of the ditch is located above an upper surface of the wiring board.

17. The method according to claim 1, wherein the middle of the sealing resin, which is located at the bottom of the ditch, is placed below a bottom surface of the heat spreader and above an upper surface of the wiring board.

18. The method according to claim 1, wherein the resin sealing body includes a first metal layer on a front surface and a second metal layer on a back surface at a dicing region.

19. The method according to claim 1, wherein the resin sealing body includes:
a surface comprising a first scribe line including a surface that comprises a metal of the heat spreader; and
another surface comprising a second scribe line on the surface of the back side of the wiring board, a surface of the second scribe line being non-metal.

20. A semiconductor device manufacturing method, said method comprising:
cutting a resin sealing body into a plurality of pieces, the resin sealing body comprising a plurality of semiconductor chips mounted on a wiring board, a heat spreader disposed above the plurality of the semiconductor chips, and a sealing resin filled between the wiring board and the heat spreader,
wherein the cutting the resin sealing body includes:
shaving the resin sealing body from a side of the heat spreader; and
shaving the resin sealing body from a side of the wiring board,
wherein the shaving the resin sealing body from the side of the wiring board is carried out after the shaving from the side of the heat spreader,
wherein the resin sealing body is completely cut off by the shaving from the side of the wiring board; and
mounting a group of ball-like electrodes at a back side of the wiring board prior to the shaving from the side of the wiring board and the shaving from the side of the heat spreader,
wherein the heat spreader comprises a metal,
wherein the shaving the resin sealing body from the side of the heat spreader includes shaving the resin sealing body with a first blade,
wherein the heat spreader is completely cut off in the shaving the resin sealing body from the side of the heat spreader,
wherein a width of a ditch to be formed by the shaving the resin sealing body from the side of the heat spreader is wider than a width of a slit to be formed by the shaving the resin sealing body from the side of the wiring board,
wherein the shaving the resin sealing body from the side of the wiring board includes shaving the resin sealing body with a second blade, and
wherein the shaving the resin sealing body from the side of the heat spreader forms the ditch extending from a surface of the heat spreader to a middle of the sealing resin, and the shaving the resin sealing body from the side of the wiring board forms the slit extending from a surface of the back side of the wiring board to a bottom of the ditch formed in the sealing resin.
